(19) United States
(12) Patent Application Publication
(10) Pub. No.: US 2023/0017450 A1
(43) Pub. Date: Jan. 19, 2023

(54) SEMICONDUCTOR STRUCTURE AND FABRICATION METHOD

(71) Applicant: CHANGXIN MEMORY TECHNOLOGIES, INC., Hefei (CN)

(72) Inventors: Yong LU, Hefei (CN); Zhongyuan LI, Hefei (CN); Junhe QUAN, Hefei (CN); Xiaojie SONG, Hefei (CN); Qiuhu PANG, Hefei (CN)

(21) Appl. No.: 17/946,000

(22) Filed: Sep. 15, 2022

(30) Foreign Application Priority Data
Jul. 5, 2022 (CN) 202210792654.7

(51) Int. Cl. H01L 27/108

(52) U.S. Cl. CPC H01L 27/10885; H01L 27/10888; H01L 27/10855

(57) ABSTRACT

Embodiments provide a semiconductor fabrication method. The method includes: providing a substrate including an active layer; and forming a bit line contact layer and a bit line extending along a first direction, two sides of the bit line contact layer being in contact with the active layer and the bit line. Forming the bit line includes: forming a bit line stack including a semiconductor layer and a conductive layer stacked in sequence, the semiconductor layer covering a surface of the substrate and a surface of the bit line contact layer; etching part of the bit line stack to form initial bit lines arranged at intervals, the initial bit lines including a plurality of conductive lines; performing oxidation treatment on the semiconductor layer exposed between adjacent conductive lines to form an oxide layer, the semiconductor layer not oxidized being used as a semiconductor connection layer; and removing the oxide layer.

### CROSS-REFERENCE TO RELATED APPLICATION

This application claims priority to Chinese Patent Application No. 202210792654.7, titled “SEMICONDUCTOR STRUCTURE AND FABRICATION METHOD” and filed to the State Patent Intellectual Property Office on Jul. 5, 2022, the entire contents of which are incorporated herein by reference.

### TECHNICAL FIELD

Embodiments of the present disclosure relate to the field of semiconductor, and more particularly, to a semiconductor structure and a fabrication method.

### BACKGROUND

With continuous development of integrated circuit processes and fabrication technologies, to improve an integration level of integrated circuits, critical dimensions of transistor (MOS) devices are continuously reduced. Under a process node such as a high-dielectric material metal gate (HKMG) and a fin field-effect transistor (Finfet), a series of problems need to be faced while increasing an operating speed of the MOS devices and reducing power consumption of the MOS devices.

How to improve electrical properties of bit lines while forming the MOS devices having smaller critical dimensions has become an important problem to be solved urgently by those skilled in the art.

### SUMMARY

Embodiments of the present disclosure provide a semiconductor structure and a fabrication method, which are at least advantageous to improving electrical properties of bit lines.

According to some embodiments of the present disclosure, one aspect of the embodiments of the present disclosure provides a method for fabricating a semiconductor structure, including: providing a substrate, where the substrate comprises an active layer; forming a bit line contact layer, where the bit line contact layer is positioned in the substrate and is in contact with the active layer; and forming a bit line extending along a first direction, where the bit line is positioned above the substrate and is in contact with a side of the bit line contact layer distant from the active layer, and the first direction is parallel to a surface of the substrate. The forming the bit line includes: forming a bit line stack, where the bit line stack includes a semiconductor layer and a conductive layer stacked in sequence, and the semiconductor layer covers the surface of the substrate and a surface of the bit line contact layer; etching part of the bit line stack to form initial bit lines arranged at intervals, where the initial bit lines include a plurality of conductive lines; performing oxidation treatment on the semiconductor layer exposed between adjacent conductive lines to form an oxide layer, where the semiconductor layer not oxidized is used as a semiconductor connection layer; and removing the oxide layer, where the semiconductor connection layer and the initial bit lines jointly serve as the bit line.

According to some embodiments of the present disclosure, another aspect of the embodiments of the present disclosure further provides a semiconductor structure, which includes: a substrate, an active layer positioned in the substrate, and a word line extending along a second direction; a bit line contact layer, where the bit line contact layer includes a plurality of contact plugs arranged at intervals, the plurality of contact plugs are positioned in the substrate and are in contact with the active layer, and surfaces of the plurality of contact plugs are flush with a surface of the substrate; and a bit line extending along a first direction, where the bit line is positioned on the substrate and is in contact with sides of the plurality of contact plugs distant from the active layer; where the first direction and the second direction intersect, and are both parallel to the surface of the substrate.

### BRIEF DESCRIPTION OF THE DRAWINGS

Exemplary descriptions of one or more embodiments are made by means of pictures in corresponding drawings, and these exemplary descriptions do not constitute a limitation on the embodiments. Unless otherwise stated, the pictures in the drawings do not constitute a scale limitation. Exemplary descriptions are made to one or more embodiments with reference to pictures in the corresponding drawings, and these exemplary descriptions do not constitute limitations on the embodiments. Unless otherwise stated, the figures in the accompanying drawings do not constitute a scale limitation. To describe the technical solutions of the embodiments of the present disclosure or those of the prior art more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a vertical view of a semiconductor structure provided by an embodiment of the present disclosure;

FIG. 2 is a schematic structural diagram along A-A′ section of a semiconductor structure provided by an embodiment of the present disclosure;

FIG. 3 is a schematic structural diagram along A-A′ section of another semiconductor structure provided by an embodiment of the present disclosure;

FIG. 4 is a schematic structural diagram along B-B′ section of a semiconductor structure provided by an embodiment of the present disclosure; and

FIGS. 5 to 11 are schematic cross-sectional structural diagrams of a semiconductor structure corresponding to each step of a method for fabricating the semiconductor structure provided by an embodiment of the present disclosure.

### DETAILED DESCRIPTION

As can be known from the background art, electrical properties of bit lines of a semiconductor structure in the existing technology are poor.

Based on analysis, it is found that one of reasons for the poor electrical properties of the bit lines of the semiconductor structure is that when the size is reduced to a certain size, due to requirement of high aspect ratio for a capacitor contact hole formed between the bit lines, challenges of etching the bit lines are becoming more and more stringent. For example, the size of the existing bit line has reached 10 nm, and the bottom of the bit line is necked down due to an etching effect, which may cause the bit line to break, thereby adversely affecting the electrical properties of the bit line.

Embodiments of the present disclosure provide a semiconductor structure and a fabrication method. In the embodiments of the present disclosure, the bit line is formed by means of two-step etching. In the first step, part of the bit line is etched to form initial bit lines arranged at intervals; in the second step, the semiconductor layer exposed is oxidized to form an oxide layer, and then the oxide layer is removed. In this way, a uniform bit line structure is formed. In this way, forming the bit line by means of twice etching may avoid problems such as over etching or under etching caused by the hole etching effect of high aspect ratio during one-time etching, thereby preventing from adversely affecting the electrical properties of the bit line. In addition, the oxide layer formed may be used as the protective layer of the semiconductor layer to avoid excessive surface defects of a bottom film layer (semiconductor connection layer) of the bit line, which is advantageous to improving the electrical properties of the bit line.

The embodiments of the present disclosure will be described in detail below in conjunction with the accompanying drawings. However, a person of ordinary skill in the art may understand that in the embodiments of the present disclosure, many technical details are put forward such that a reader can better understand the present disclosure. However, the technical solutions requested to be protected by the present disclosure may also be implemented even without these technical details or various variations and modifications based on the following embodiments.

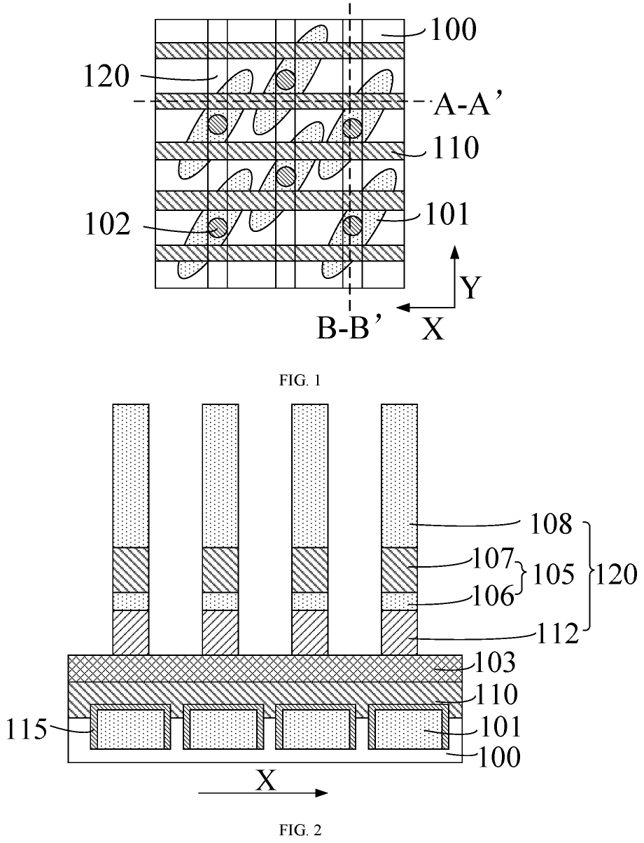

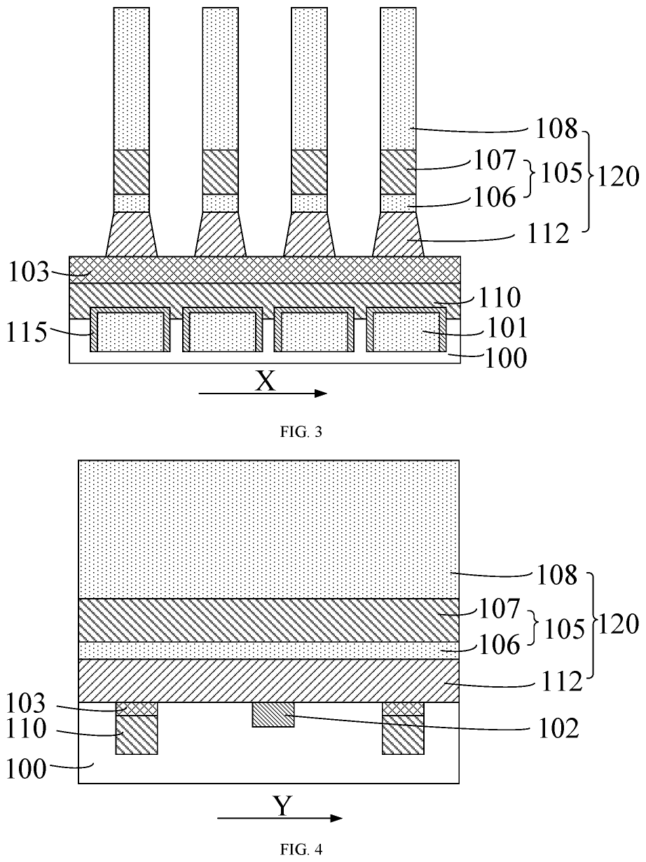

FIG. 1 is a vertical view of a semiconductor structure provided by an embodiment of the present disclosure; FIG. 2 is a schematic structural diagram along A-A′ section of a semiconductor structure provided by an embodiment of the present disclosure; FIG. 3 is a schematic structural diagram along A-A′ section of another semiconductor structure provided by an embodiment of the present disclosure; and FIG. 4 is a schematic structural diagram along B-B′ section of a semiconductor structure provided by an embodiment of the present disclosure. It should be noted that, to facilitate the display of the positions and connection relationship between the bit line, an active layer and a word line, in the vertical view of the semiconductor structure shown in FIG. 1, the substrate and the bit line are in a see-through state. That is, what is inside the substrate and the bit line can be seen, or the top or bottom of the bit line can be seen through the bit line.

Referring to FIG. 1 to FIG. 4, one aspect of the embodiments of the present disclosure provides a semiconductor structure, which includes: a substrate 100, an active layer 101 positioned in the substrate 100, and a word line 110 extending along a second direction X; a bit line contact layer 102, where the bit line contact layer 102 includes a plurality of contact plugs arranged at intervals, the plurality of contact plugs are positioned in the substrate 100 and are in contact with the active layer 101, and surfaces of the plurality of contact plugs are flush with a surface of the substrate 100; and a bit line 120 extending along a first direction Y, where the bit line 120 is positioned on the substrate 100 and is in contact with sides of the plurality of contact plugs distant from the active layer 101; where the first direction Y and the second direction X intersect, and are both parallel to the surface of the substrate 100.

In some embodiments, the substrate 100 may be a stacked structure, which includes a semiconductor substrate and a first isolation layer stacked, and the active layer 101 and the word lines 110 are positioned in the isolation layer. A material of the semiconductor substrate may be any one of silicon, germanium, silicon carbide or silicon germanium. The semiconductor substrate may be doped with N-type doping elements or P-type doping elements, so the semiconductor structure is an nMOSFET or a pMOSFET. A material of the first isolation layer is silicon oxide, silicon nitride or other insulating materials having low dielectric constant k.

In some embodiments, a source region and a drain region of the semiconductor structure are subsequently formed in the active layer 101, a region where the active layer 101 is adjacent to the word line is a channel region, and the source region and the drain region are positioned in two sides of the channel region. One of the source region or the drain region of the active layer 101 is electrically connected to the bit line 120, and other one of the source region or the drain region of the active layer 101 is electrically connected to a storage structure.

In some embodiments, a material of the active layer 101 may be a semiconductor material or an amorphous material, where the semiconductor material may include any one of silicon, germanium, silicon carbide, or germanium silicon. The material of the active layer 101 is the semiconductor material, which may be close to a lattice between the bit line contact layers 102, thereby forming a good contact and reducing a contact resistance of the semiconductor structure. Either one or both of the active layers 101 in the source region and the drain region are doped with a P-type doping element or an N-type doping element. In some embodiments, the N-type doping element may be a Group-V element such as phosphorus (P) element, bismuth (Bi) element, antimony (Sb) element or arsenic (As) element, and the P-type doping element may be a Group-III element such as boron (B) element, aluminum (Al) element, gallium (Ga) element or indium (In) element. The amorphous material has a gap inside and has higher carrier mobility, which can reduce a thickness of the active layer 101, reduce a line width of the semiconductor structure within a limited cell area, and further improve the storage density of the semiconductor structure. The amorphous material includes at least one of an indium gallium zinc oxide (IGZO), an indium tin oxide (ITO), an indium gallium zinc tin oxide (IGZTO), or indium tungsten oxide (IWO).

In some embodiments, the substrate 100 further includes an isolation layer 103 and a gate oxide layer 115, where the isolation layer 103 is positioned on the surface of the word line 110, and the gate oxide layer 115 is positioned between the word line 110 and the active layer 101 to isolate the word line 110 from the active layer 101. A material of the isolation layer 103 is silicon oxide, silicon carbide or silicon nitride. A material of the gate oxide layer 115 may be silicon nitride, silicon oxide or other materials having high dielectric constant.

In some embodiments, the bit line 120 and the active layer 101 are electrically connected by means of the bit line contact layer 102, where the bit line contact layer 102 is configured to reduce a contact resistance between the bit line 120 and the active layer 101. The material of the bit line contact layer 102 may be a semiconductor material, titanium nitride, or metal silicide. The semiconductor material may be doped polysilicon. The doped polysilicon forms a good ohmic contact with crystalline silicon of the active layer 101 to have a lower contact resistance, thereby reducing the contact resistance between the bit line and the active layer 101. The metal silicide may be cobalt silicide, nickel silicide, titanium silicide, tungsten silicide, tantalum silicide, or molybdenum silicide. The metal silicide has lower resistivity (less than 0.01 time that of polysilicon), good thermal stability, better electromigration resistance, and good compatibility with silicon processes.

In some embodiments, the bit line 120 extends along the first direction Y, the bit line 120 is a metal bit line, and the bit line 120 includes a semiconductor connection layer 112, a conductive layer 105 and a protective layer 108 stacked in sequence, where the semiconductor connection layer 112 is electrically connected to the contact plug. The conductive layer 105 includes a first conductive layer 106 and a second conductive layer 107. A material of the second conductive layer 107 of the bit line 120 may be metal such as tungsten or molybdenum. The metal has smaller resistance, which is advantageous to improving the conductivity of the bit line 120 and the active layer 101. The first conductive layer 106 of the bit line 120 is a metal barrier layer configured to prevent the metal of the second conductive layer 107 from diffusing to the substrate 100. A material of the first conductive layer 106 may be titanium nitride or titanium silicon nitride. In some other embodiments, the bit line 120 may be a semiconductor bit line, and a material of the semiconductor bit line may be silicon, germanium, silicon germanium, silicon carbide or polysilicon. In addition, the semiconductor bit line is doped with the same type of doping element as the active layer 101, and the doping element may be used as a carrier, which can improve migration and diffusion of the carrier between the bit line 120 and the active layer 101, and thus it is advantageous to improving the conductivity of the bit line 120 and the active layer 101.

In some embodiments, as shown in FIG. 2, a section shape of the semiconductor connection layer 112 along the second direction Y is a rectangle. In some other embodiments, as shown in FIG. 3, the section shape of the semiconductor connection layer 112 along the second direction Y is a trapezoid, which may be an isosceles trapezoid. That is, a width of a top surface of the semiconductor connection layer 112 is smaller than a width of a bottom surface of the semiconductor connection layer 112 along a direction perpendicular to the surface of the substrate 100. Base angles of the isosceles trapezoid form acute angles and have better stability, thereby providing sufficient support to a film layer structure on the top surface of the semiconductor connection layer 112, and avoiding contour deformation of the bit line 120 and adversely affecting the electrical properties of the bit line 120. A material of the semiconductor connection layer 112 is undoped polysilicon or doped polysilicon. A material of the protective layer 108 is silicon nitride, silicon oxide, silicon carbide, or silicon oxynitride.

In some embodiments, the semiconductor structure may further include a storage structure, which is positioned between adjacent bit lines 110. The storage structure may be a capacitor structure, and the semiconductor structure may form one transistor corresponding to one capacitor structure (1T-1C). There is a first dielectric layer between adjacent capacitor structures, and a material of the first dielectric layer may include any one or more of silicon oxide, silicon nitride, and high-k materials, where the high-k materials may include hafnium oxide, zirconium oxide, aluminium oxide, lanthanum oxide, titanium oxide, tantalum oxide, niobium oxide, or strontium titanate.

In some embodiments, an angle between the first direction Y and the second direction X is greater than 0° and less than 180°. Further, the angle between the first direction Y and the second direction X is 90°, that is, the first direction Y and the second direction X are perpendicular to each other.

It should be noted that the substrate 100 also includes other memory structures other than the word line 110 and the active layer 101, such as a shallow trench isolation (STI) structure, etc. Because the other memory structures do not involve core technologies of the present disclosure, they are not described in detail here. Those skilled in the art can understand that the substrate 100 also includes other memory structures other than the word line 110 and the active layer 101 to ensure normal operation of the memory.

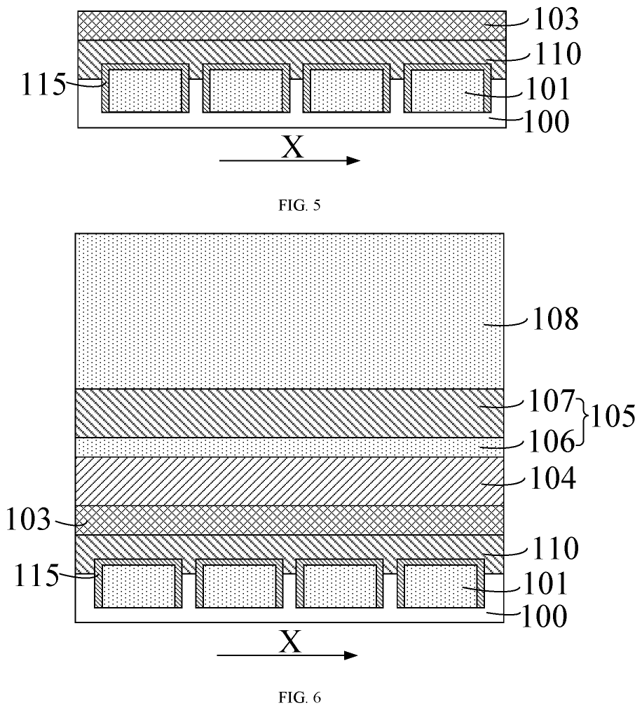

Correspondingly, FIGS. 5 to 11 are schematic cross-sectional structural diagrams of the semiconductor structure corresponding to each step of a method for fabricating the semiconductor structure provided by an embodiment of the present disclosure.

Referring to FIG. 5, a substrate 100 is provided, and the substrate 100 is internally provided with an active layer 101 and a word line 110 extending along a second direction X. A bit line contact layer 102 (referring to FIG. 4) is formed, and the bit line contact layer 102 (referring to FIG. 4) is positioned in the substrate 100 and is in contact with the active layer 101.

In some embodiments, the active layer 101 includes a channel region, a source region and a drain region arranged in sequence. The word line 110 is in contact with the active layer 101 in the channel region, the bit line contact layer 102 is electrically connected to one of the active layer 101 in the source region or the active layer 101 in the drain region, and a storage structure formed subsequently is electrically connected to other one of the active layer 101 in the source region or the active layer 101 in the drain region. A material of the active layer 101 is a semiconductor material or an amorphous material, where the semiconductor material may include any one of silicon, germanium, silicon carbide, or germanium silicon. The amorphous material includes at least one of an indium gallium zinc oxide (IGZO), an indium tin oxide (ITO), an indium gallium zinc tin oxide (IGZTO), or indium tungsten oxide (IWO).

In some embodiments, each film layer of the word line 110 and an isolation layer 103 may be formed by means of chemical vapor deposition (CVD) or physical vapor deposition (PVD), for example. The CVD includes atomic layer deposition (ALD) and plasma enhanced chemical vapor deposition (PECVD).

In some embodiments, the bit line contact layer 102 is configured to reduce the contact resistance between the bit line and the active layer 101, and the material of the bit line contact layer 102 may be a semiconductor material, titanium nitride, or a metal silicide. The semiconductor material may be doped polysilicon. The metal silicide may be titanium silicide, tungsten silicide, tantalum silicide, or molybdenum silicide. A fabrication method for forming the bit line contact layer 102 may include: first etching the substrate 100 to form a bit line contact hole whose bottom exposes the active layer 101, and depositing and in-situ doping to form the bit line contact layer 102 including the doped polysilicon; or, depositing a metal layer, and annealing to form the bit line contact layer 102 including the metal silicide.

Referring to FIG. 1 to FIG. 4 and FIG. 6 to FIG. 11, the bit line 120 extending along the first direction Y is formed, and the bit line 120 is positioned above the substrate 100 and is in contact with a side of the bit line contact layer 102 distant from the active layer 101. The first direction Y is parallel to the surface of the substrate 100.

In some embodiments, as shown in FIG. 2, a section shape of the semiconductor connection layer 112 along the second direction Y is a rectangle. In some other embodiments, as shown in FIG. 3, the section shape of the semiconductor connection layer 112 along the second direction Y is a trapezoid, which may be an isosceles trapezoid. That is, a width of a top surface of the semiconductor connection layer 112 is smaller than a width of a bottom surface of the semiconductor connection layer 112 along a direction perpendicular to the surface of the substrate 100. The material of the semiconductor connection layer 112 is undoped polysilicon or doped polysilicon. The material of the protective layer 108 is silicon nitride, silicon oxide, silicon carbide, or silicon oxynitride.

In some embodiments, referring to FIG. 6, a bit line stack is formed, and the bit line stack includes a semiconductor layer 104 and a conductive layer 105 stacked in sequence, where the semiconductor layer 104 covers the surface of the substrate 100 and the surface of the bit line contact layer 102 (referring to FIG. 4). The protective layer 108 is formed, and the protective layer 108 is positioned on the surface of the conductive layer 105 distant from the substrate 100.

In some embodiments, the semiconductor layer 104, the first conductive layer 106, the second conductive layer 107 and the protective layer may be formed by means of chemical vapor deposition (CVD) or physical vapor deposition (PVD), etc.

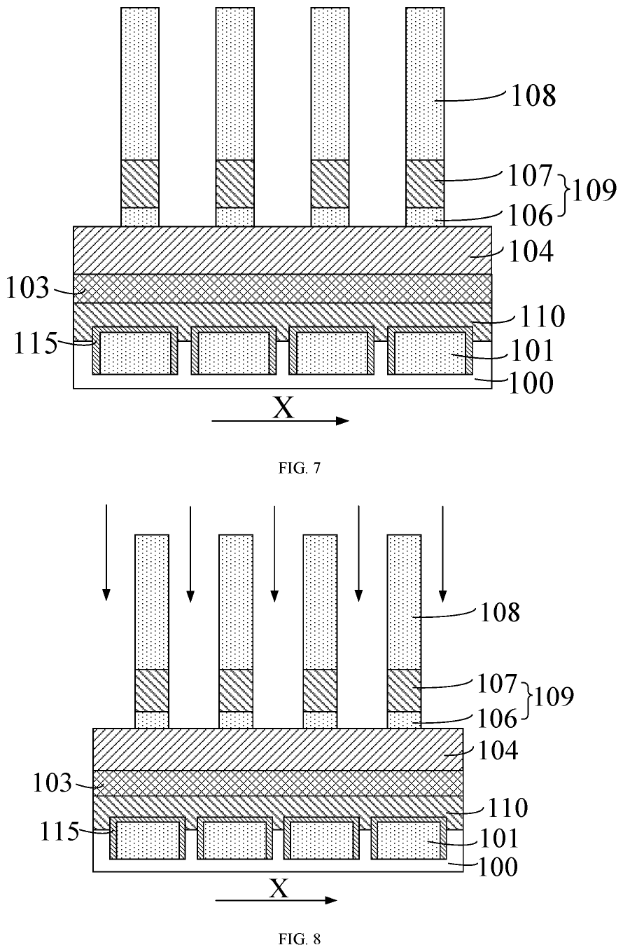

Referring to FIG. 7, along the first direction Y, part of the bit line stack is etched to form initial bit lines arranged at intervals, where the initial bit lines include a plurality of conductive lines 109.

In some embodiments, only the conductive layer 105 (referring to FIG. 6) is etched to form the plurality of conductive lines 109 extending along the first direction Y, and the surface of the semiconductor layer 104 is exposed between adjacent conductive lines 109. The protective layer 108 is etched simultaneously when the conductive layer 105 (referring to FIG. 6) is etched. The conductive layer 105 (referring to FIG. 6) is etched by means of a dry etching process or a wet etching process.

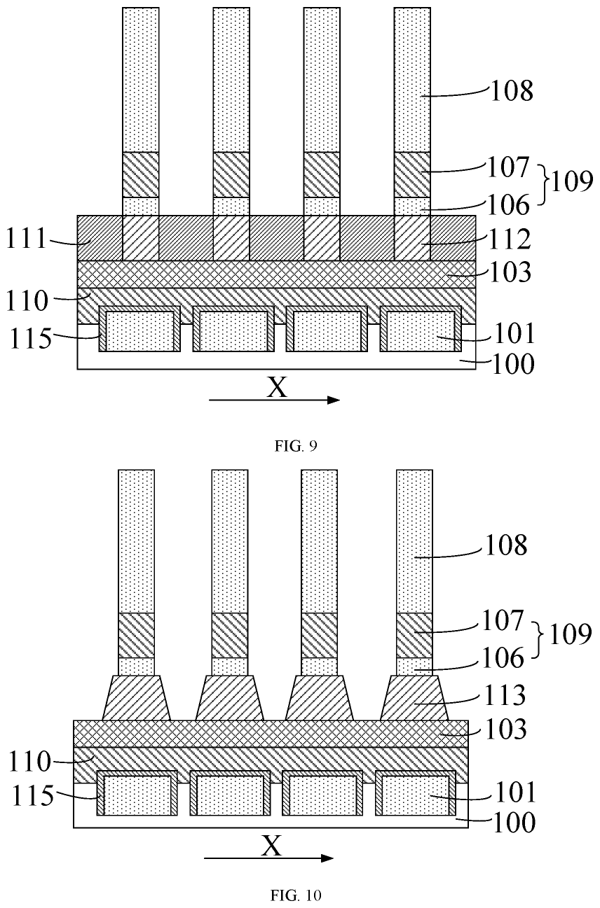

Referring to FIGS. 8 to 9, the semiconductor layer 104 exposed between adjacent conductive lines 109 is oxidized to form an oxide layer 111, and the unoxidized semiconductor layer 104 is used as the semiconductor connection layer 112.

In some embodiments, oxygen-atom ion implantation is performed on the semiconductor layer 104 exposed, and oxygen ions are implanted into the semiconductor layer 104 to form an oxygen ion implantation layer. In this way, forming the oxide layer 111 by means of the ion implantation process may control the depth of ion implantation to avoid diffusion to the substrate 100. The lateral diffusion of the ion implantation is small, to ensure that the semiconductor layer 104 positioned below the initial bit lines is not oxidized or oxidized as little as possible, thereby ensuring that the width of the bit line is as large as possible, and ensuring the transmission capacity of the bit line. In the ion implantation process, ions are implanted to directly combine with atoms or molecules on the material surface of the semiconductor layer 104, to form a modified layer (i.e., an oxygen ion implantation layer). There is no clear interface between a material of the oxygen ion implantation layer and the material of the semiconductor layer 104, therefore the combination is firm, no phenomenon of shedding occurs, there are fewer lattice defects, and there is less damage to the semiconductor connection layer 112 formed, thereby avoiding degradation of the electrical properties of the bit line.

Process steps of the oxygen-atom ion implantation process include: accelerating oxygen atoms in a vacuum and low-temperature environment, such that the oxygen atoms accelerated directly enter the semiconductor layer 104; and performing annealing or laser annealing in the low-temperature environment such that the polysilicon reacts with the oxygen atoms to form silicon dioxide. In some embodiments, the process parameters of the oxygen-atom ion implantation process need to ensure that the semiconductor layer 104 has an oxygen atom layer of a certain thickness, which is converted into the oxide layer 111 in the subsequent annealing treatment. Moreover, it is avoidable as much as possible that the oxygen atoms are only positioned in the semiconductor layer 104 exposed or only a small number of oxygen atoms are positioned in the semiconductor layer 104 not exposed, to ensure greater width of the bit line formed subsequently. In this way, it is ensured that the resistance of the bit line is smaller, and thus the electrical properties of the bit line can be improved.

In some embodiments, the oxygen ion implantation layer is thermally treated to form the oxide layer. It is to be understood that, the process parameters for the heat treatment also need to satisfy a certain thickness of the oxygen atom layer positioned in the semiconductor layer 104, which is converted into the oxide layer 111 during the heat treatment. Moreover, it is avoidable as much as possible that the oxygen atoms are only positioned in the semiconductor layer 104 exposed or only a small number of oxygen atoms are positioned in the semiconductor layer 104 not exposed, to ensure greater width of the bit line formed subsequently. In this way, it is ensured that the resistance of the bit line is smaller, and thus the electrical properties of the bit line can be improved.

In some embodiments, an orthographic projection of the oxide layer 111 on the surface of the substrate 100 does not overlap with an orthographic projection of the semiconductor connection layer 112 on the surface of the substrate 100. In this way, the section shape of the semiconductor connection layer 112 of the bit line formed subsequently is rectangular, the outline of the bit line is clearer, and the size of the bit line is smaller, such that it is advantageous to reducing the critical dimension of the semiconductor structure, and thus increasing the storage density of the semiconductor structure.

Referring to FIG. 2, the oxide layer 111 (referring to FIG. 9) is removed, and the semiconductor connection layer 112 and the initial bit line together serve as the bit line 120.

In some embodiments, the semiconductor connection layer 112, the first conductive layer 106, the second conductive layer 107 and the protective layer 108 together constitute the bit line. The oxide layer 111 (referring to FIG. 9) is removed by means of a wet etching process, a wet etching solution includes a dilute hydrofluoric acid solution, and a mass concentration range of the dilute hydrofluoric acid solution is 40% to 60%. Thus, the mass concentration range of the dilute hydrofluoric acid solution not only can satisfy the removal of the oxide layer, but also can ensure smaller damage to a side wall of the first conductive layer 106 and a side wall of the second conductive layer 107. In this way, it is avoidable that degradation of the electrical properties of the bit line is caused by etching defects on the side wall of the first conductive layer 106 and the side wall of the second conductive layer 107.

In the method for fabricating the semiconductor structure provided in the embodiments of the present disclosure, the semiconductor layer 104 exposed between adjacent conductive lines 109 is oxidized to form an oxide layer 111, the semiconductor layer 104 not oxidized is used as a semiconductor connection layer 112, the oxide layer 111 is then removed to form the bit line 120, and the oxide layer 111 formed may be used as the protective layer of the bit line 120, to avoid an etching effect of high aspect ratio of the capacitor contact hole when the bit line 120 is formed, which causes the width of the bit line 120 to be too narrow or even causes the bit line 120 to break due to necking-down at the bottom of the bit line 120. In this way, it may avoid situations such as increase of the resistance value of the bit line 120 and failure of the bit line 120, which is advantageous to improving the electrical properties of the bit line 120. The oxidation treatment is an oxygen-atom ion implantation process, which may ensure the size of the bit line formed by controlling a depth of ion implantation and a range of diffusion, and there is neither interface nor lattice defects between the oxide layer 111 formed and the semiconductor connection layer 112, such that the electrical properties of the bit line can be ensured.

Other embodiment of the present disclosure also provides a method for fabricating the semiconductor structure. The method for fabricating the semiconductor structure provided in the other embodiment of the present disclosure is substantially the same as the method for fabricating the semiconductor structure provided in the previous embodiment, and main differences lie in that the method for fabricating the semiconductor structure provided in the other embodiment of the present disclosure further includes forming the semiconductor lines after the conductive lines are formed. In addition, the method for forming the oxide layer in the method for fabricating the semiconductor structure provided in the other embodiment of the present disclosure is also different from the method for forming the oxide layer in the method for fabricating the semiconductor structure provided in the previous embodiment. The method for fabricating the semiconductor structure provided by the other embodiment of the present disclosure will be described in detail below with reference to the accompanying drawings.

Referring to FIG. 5 and FIG. 6, a substrate 100 is provided, and the substrate 100 is internally provided with an active layer 101 and a word line 110 extending along a second direction X. A bit line contact layer 102 (referring to FIG. 4) is formed, and the bit line contact layer 102 (referring to FIG. 4) is positioned in the substrate 100 and in contact with the active layer 101. A bit line stack is formed, and the bit line stack includes a semiconductor layer 104 and a conductive layer 105 stacked in sequence, where the semiconductor layer 104 covers the surface of the substrate 100 and the surface of the bit line contact layer 102 (referring to FIG. 4). The protective layer 108 is formed, and the protective layer 108 is positioned on the surface of the conductive layer 105 distant from the substrate 100.

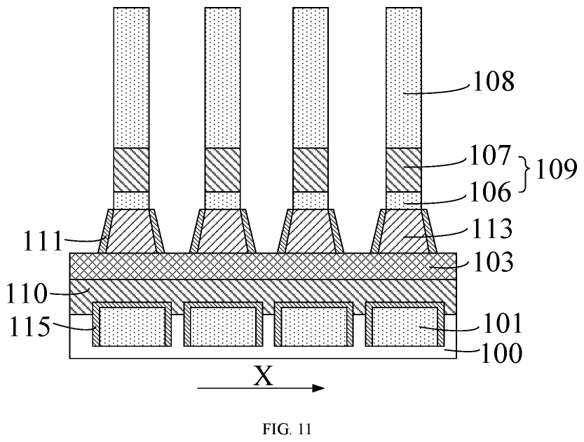

Referring to FIG. 10, the conductive layer 105 (referring to FIG. 6) is etched to form a plurality of conductive lines 109 extending along the first direction Y; and the semiconductor layer 104 (referring to FIG. 6) is etched to form semiconductor lines 113 arranged at intervals, where conductive lines 109 and the semiconductor line 113 together serve as the initial bit lines.

In some embodiments, an orthographic projection of the conductive line 109 on the surface of the substrate is positioned within an orthographic projection of the top surface of the semiconductor line 113 on the surface of the substrate 100. The width of the top surface of the semiconductor line 113 formed by etching is smaller than that of the bottom surface of the semiconductor line 113. In some embodiments, the section shape of the semiconductor line 113 along the second direction X is a trapezoid. That is, an angle formed between a side surface of the semiconductor line 113 and the bottom surface of the semiconductor line 113 is less than 90°. An acute angle structure (less than 90°) may enable the semiconductor line 113 formed to be a stable structure, thereby avoiding the situation that the outline of the bit line is deformed or even broken due to film layers stacked on the semiconductor line positioned at the bottom of the bit line.

In some embodiments, the process parameters of etching the semiconductor layer 104 (referring to FIG. 6) to form the semiconductor lines 113 arranged at intervals include: injecting helium gas into an etching gas after the conductive lines 109 are formed, and controlling a reaction temperature between 30° C. and 40° C., and a current ratio between 0.8 and 1.2. It is to be understood that, the above process parameters are set to ensure that the semiconductor lines 113 formed satisfy the following conditions: the orthographic projection of the conductive line 109 on the surface of the substrate is positioned within the orthographic projection of the top surface of the semiconductor line 113 on the surface of the substrate 100. That is, those skilled in the art may set relevant parameters according to the structural features of the conductive lines and the semiconductor lines to make substitutions.

Referring to FIG. 11, the oxide layer 111 is formed on the side surface of the semiconductor line 113, a remaining part of the semiconductor layer 104 serves as the semiconductor connection layer 112, and the oxide layer 111 is positioned on the side surface of the semiconductor connection layer 112.

In some embodiments, a wet oxidation process is performed on the exposed side surface of the semiconductor line 113 to form the oxide layer 111. The wet oxidation process includes: oxidizing the side surface of the semiconductor line 113 using a hydrofluoric acid solution in an ozone environment. The wet oxidation process may also be a wet cleaning process, and a cleaning solution of the wet cleaning process includes an HF/O₃ solution. The wet cleaning process may remove particles attached to the semiconductor layer, and no waste liquid treatment is required, thereby reducing cleaning process of water washing and chemical reagents, and thus saving steps and costs. The cleaning agent of the wet cleaning process includes hydrofluoric acid HF, ozone O₃, and water vapor; and a reaction temperature is room temperature. The wet cleaning process is also called Astec Clean (AC) cleaning method, including an HF/O₃ tank cleaning method and an HF/O₃ single-chip cleaning method. A reaction mechanism of the wet cleaning process is as below: ozone oxidizes organic particles on the surface of the semiconductor layer into carbon dioxide and water, to achieve the purpose of removing organic matters on the surface of the semiconductor layer, and a dense oxide film is simultaneously formed on the surface of the semiconductor layer. The hydrofluoric acid can remove metal particles on the surface, and part of the oxide film formed by means of ozone oxidation is etched, and the particles attached to the surface of the oxide film are removed. The wet cleaning process may also include a surfactant, which can prevent the particles that have been removed from reabsorbing on the surface of the semiconductor layer. After the wet cleaning process, the method further includes: performing spin drying on the semiconductor structure. For example, nitrogen may be used as an ambient gas for atmospheric drying. In some other embodiments, the oxide layer may be formed by means of an Astec Dry (AD) method, and the process includes liquid reaction and gas phase treatment. First, the semiconductor structure is placed in an HF/O₃ drying tank, and after a certain period of time, the semiconductor structure is lifted out of a liquid level and directly reacts with high-concentration ozone sprayed from an O₃ nozzle above the drying tank, thereby forming a dense oxide layer on the surface of the semiconductor layer. It is to be understood that, in the above oxidation treatment, a thin oxide layer is also formed on the surface of the conductive layer. The thin oxide layer is removed when the oxide layer is removed.

In some embodiments, central axes of the semiconductor lines overlap with central axes of the conductive lines, and along a direction parallel to the surface of the substrate 100, a differential between widths of top surfaces of the semiconductor lines 113 and widths of bottom surfaces of the conductive lines 109 is greater than or equal to two times a thickness of the oxide layer 111. In this way, the size of the bit line formed subsequently is larger, and the resistance of the bit line is smaller, which is advantageous to improving the electrical properties of the bit line. Having a thickness of 0.5 nm to 2 nm, the oxide layer 111 may be used as a protective layer to protect the side surface of the semiconductor connection layer when forming the semiconductor lines, thereby avoiding too many defects on the surface of the bit line formed. The oxide layer 111 should not be too thick, thereby preventing an etchant from causing etching damage to the surface of the conductive layer during the removal of the oxide layer 111.

Referring to FIG. 3, the oxide layer 111 is removed, and the semiconductor connection layer 112 and the initial bit line together serve as the bit line 120.

In some embodiments, the oxide layer 111 is removed by means of a wet etching process, a wet etching solution includes a dilute hydrofluoric acid solution, and a mass concentration range of the dilute hydrofluoric acid solution is 40% to 60%.

In the embodiments of the present disclosure, the oxide layer 111 is formed by oxidizing the semiconductor layer 104 exposed between the adjacent conductive lines 109, the semiconductor layer 104 not oxidized is used as the semiconductor connection layer 112, the oxide layer 111 is then removed to form the bit line 120, and the oxide layer 111 formed may be used as the protective layer of the bit line 120, to avoid an etching effect of high aspect ratio of the capacitor contact hole when the bit line 120 is formed, which causes the width of the bit line 120 to be too narrow or even causes the bit line 120 to break due to necking-down at the bottom of the bit line 120. In this way, it may avoid situations such as increase of the resistance value of the bit line 120 and failure of the bit line 120, which is advantageous to improving the electrical properties of the bit line 120. The oxidation treatment is a wet oxidation process, which may remove part of the metal particles and organic matter particles attached to the surface of the semiconductor layer, thereby reducing the surface defects of the semiconductor connection layer 112 formed. Moreover, the oxide layer formed on the surface of the conductive layer may also be used as a protective layer in the process step of removing the oxide layer, to prevent an etching damage layer from being formed on the surface of the conductive layer.

Those of ordinary skill in the art can understand that the above-mentioned embodiments are some embodiments for realizing the present disclosure, but in practical applications, various changes may be made to them in form and details without departing from the spirit and scope of the present disclosure. Any person skilled in the art can make their own changes and modifications without departing from the spirit and scope of the present disclosure. Therefore, the protection scope of the present disclosure shall be subject to the scope defined by the claims.

What is claimed is:

1. A method for fabricating a semiconductor structure, comprising:
providing a substrate, the substrate comprising an active layer;
forming a bit line contact layer, the bit line contact layer being positioned in the substrate and being in contact with the active layer; and
forming a bit line extending along a first direction, the bit line being positioned above the substrate and being in contact with a side of the bit line contact layer distant from the active layer, wherein the first direction is parallel to a surface of the substrate;
wherein the forming the bit line comprises: forming a bit line stack, the bit line stack comprising a semiconductor layer and a conductive layer stacked in sequence, and the semiconductor layer covering the surface of the substrate and a surface of the bit line contact layer;
etching part of the bit line stack to form initial bit lines arranged at intervals, the initial bit lines comprising a plurality of conductive lines;
performing oxidation treatment on the semiconductor layer exposed between adjacent two of the plurality of conductive lines to form an oxide layer, the semiconductor layer not oxidized being used as a semiconductor connection layer; and
removing the oxide layer, the semiconductor connection layer and the initial bit lines jointly serving as the bit line.

2. The method for fabricating the semiconductor structure according to claim 1, wherein the etching part of the bit line stack to form the initial bit lines arranged at intervals comprises: etching only the conductive layer to form a plurality of conductive lines extending along the first direction, a surface of the semiconductor layer being exposed between adjacent two of the plurality of conductive lines; and
the forming the oxide layer comprises: performing oxygen-atom ion implantation on the semiconductor layer exposed.

3. The method for fabricating the semiconductor structure according to claim 2, wherein the oxygen-atom ion implantation comprises: implanting oxygen ions into the semiconductor layer to form an oxygen ion implantation layer, and performing heat treatment on the oxygen ion implantation layer to form the oxide layer.

4. The method for fabricating the semiconductor structure according to claim 2, wherein an orthographic projection of the oxide layer on the surface of the substrate does not overlap with an orthographic projection of the semiconductor connection layer on the surface of the substrate.

5. The method for fabricating the semiconductor structure according to claim 1, wherein the etching part of the bit line stack to form the initial bit lines arranged at intervals comprises: etching the conductive layer to form a plurality of conductive lines extending along the first direction; and etching the semiconductor layer to form semiconductor lines arranged at intervals, the plurality of conductive lines and the semiconductor lines jointly serving as the initial bit lines; and the forming the oxide layer comprises: forming the oxide layer on side surfaces of the semiconductor lines.

6. The method for fabricating the semiconductor structure according to claim 5, wherein orthographic projections of the plurality of conductive lines on the surface of the substrate are positioned within orthographic projections of top surfaces of the semiconductor lines on the surface of the substrate.

7. The method for fabricating the semiconductor structure according to claim 6, wherein widths of the top surfaces of the semiconductor lines formed by etching are smaller than widths of bottom surfaces of the semiconductor lines.

8. The method for fabricating the semiconductor structure according to claim 6, wherein central axes of the semiconductor lines overlap with central axes of the plurality of conductive lines, and a differential between widths of top surfaces of the semiconductor lines and widths of bottom surfaces of the plurality of conductive lines is greater than or equal to two times a thickness of the oxide layer.

9. The method for fabricating the semiconductor structure according to claim 5, wherein the performing the oxidation treatment on the semiconductor layer exposed between adjacent two of the plurality of conductive lines comprises: performing a wet oxidation process on side surfaces of the semiconductor lines exposed to form the oxide layer.

10. The method for fabricating the semiconductor structure according to claim 9, wherein the wet oxidation process comprises: oxidizing the side surfaces of the semiconductor lines using a hydrofluoric acid solution in an ozone environment.

11. The method for fabricating the semiconductor structure according to claim 5, wherein process parameters of etching the semiconductor layer to form the semiconductor lines arranged at intervals comprise: injecting helium gas into an etching gas after the plurality of conductive lines are formed, and controlling a reaction temperature between 30° C. and 40° C., and a current ratio between 0.8 and 1.2.

12. The method for fabricating the semiconductor structure according to claim 1, wherein the oxide layer is removed by means of a wet etching process, a wet etching solution comprises a dilute hydrofluoric acid solution, and a mass concentration range of the dilute hydrofluoric acid solution is 40% to 60%.

13. A semiconductor structure fabricated by the method for fabricating the semiconductor structure according to claim 1, wherein the semiconductor structure comprises:
a substrate, an active layer positioned in the substrate, and a word line extending along a second direction;
a bit line contact layer, the bit line contact layer comprising a plurality of contact plugs arranged at intervals, the plurality of contact plugs being positioned in the substrate and being in contact with the active layer, and surfaces of the plurality of contact plugs being flush with a surface of the substrate; and
a bit line extending along a first direction, the bit line being positioned on the substrate and being in contact with sides of the plurality of contact plugs distant from the active layer; wherein the first direction and the second direction intersect, and are both parallel to the surface of the substrate.

14. The semiconductor structure according to claim 13, wherein the bit line comprises a semiconductor connection layer, a conductive layer and a protective layer stacked in sequence, the semiconductor connection layer being electrically connected to the plurality of contact plugs.

15. The semiconductor structure according to claim 14, wherein a section shape of the semiconductor connection layer comprises a trapezoid or a rectangle.
